(19) United States
(12) Patent Application Publication
(10) Pub. No.: US 2025/0337385 A1
(43) Pub. Date: Oct. 30, 2025

(54) ACOUSTIC WAVE DEVICE AND COMPOSITE FILTER DEVICE

(71) Applicant: Murata Manufacturing Co., Ltd., Nagaokakyo-shi (JP)

(72) Inventor: Hideki IWAMOTO, Nagaokakyo-shi (JP)

(21) Appl. No.: 19/262,545

(22) Filed: Jul. 8, 2025

Related U.S. Application Data
(63) Continuation of application No. PCT/JP2023/044681, filed on Dec. 13, 2023.

(30) Foreign Application Priority Data
Jan. 18, 2023 (JP) 2023-006033

(51) Int. Cl. H03H 9/02; H03H 9/25

(52) U.S. Cl. CPC H03H 9/02574; H03H 9/02559; H03H 9/02866; H03H 9/25

(57) ABSTRACT

An acoustic wave device includes a silicon single crystal baseplate including a main surface, a piezoelectric layer directly or indirectly on the main surface of the silicon single crystal baseplate, and an IDT electrode on the piezoelectric layer and including electrode fingers. The piezoelectric layer is a lithium niobate layer. In the main surface of the silicon single crystal baseplate, a plane orientation is (111). When Euler angles in the main surface of the silicon single crystal baseplate are (φ, θ, ψ), the ψ in the Euler angles of the silicon single crystal baseplate is about −30 degrees <ψ< about 30 degrees.

### CROSS REFERENCE TO RELATED APPLICATIONS

This application claims the benefit of priority to Japanese Patent Application No. 2023-006033 filed on Jan. 18, 2023 and is a Continuation Application of PCT Application No. PCT/JP2023/044681 filed on Dec. 13, 2023. The entire contents of each application are hereby incorporated herein by reference.

### BACKGROUND OF THE INVENTION

### 1. Field of the Invention

The present invention relates to acoustic wave devices and composite filter devices.

### 2. Description of the Related Art

Hitherto, an acoustic wave device has been widely used in, for example, a filter of a cellular phone. International Publication No. 2017/209131 discloses an example of an acoustic wave device. In the acoustic wave device, an IDT (Interdigital Transducer) electrode is provided on a composite substrate. The composite substrate includes a silicon substrate and a lithium tantalate substrate that are placed upon each other. A plane orientation of the silicon substrate is (111). The acoustic wave device is designed to suppress a bulk wave spurious component.

In the acoustic wave device described in International Publication No. 2017/209131, lithium tantalate is used as a piezoelectric layer. In this case, a bandwidth between a resonant frequency and an anti-resonant frequency cannot be made sufficiently wide. When the bandwidth is to be made wide, in the acoustic wave device described in International Publication No. 2017/209131, suppression of a spurious component becomes difficult. That is, in the acoustic wave device described in International Publication No. 2017/209131, it is not possible to provide a wide bandwidth and to suppress unnecessary waves at the same time.

### SUMMARY OF THE INVENTION

Example embodiments of the present invention provide acoustic wave devices and composite filter devices, which are each able to provide a wide bandwidth and to reduce or prevent unnecessary waves.

An acoustic wave device according to an example embodiment of the present invention includes a silicon single crystal baseplate including a main surface, a piezoelectric layer directly or indirectly on the main surface of the silicon single crystal baseplate, and an IDT electrode on the piezoelectric layer and including a plurality of electrode fingers, wherein the piezoelectric layer is a lithium niobate layer, wherein, in the main surface of the silicon single crystal baseplate, a plane orientation is (111), and when Euler angles in the main surface of the silicon single crystal baseplate are (φ, θ, ψ), the ψ in the Euler angles of the silicon single crystal baseplate is about −30 degrees <ψ< about 30 degrees.

An acoustic wave device according to another example embodiment of the present invention includes a silicon single crystal baseplate including a main surface, a piezoelectric layer directly or indirectly on the main surface of the silicon single crystal baseplate, and an IDT electrode on the piezoelectric layer and including a plurality of electrode fingers, wherein, in the main surface of the silicon single crystal baseplate, a plane orientation is (111), the piezoelectric layer includes an X axis, a Y axis, and a Z axis as crystal axes, and the piezoelectric layer is a Y-cut X-propagation lithium niobate layer, and when one direction of directions of extension of the X axis of the piezoelectric layer is a +X direction, an angle of a corner defined by the +X direction and a [1-10] direction in the silicon single crystal baseplate is about −15 degrees to about 15 degrees.

A composite filter device according to an example embodiment of the present invention includes a common connection terminal and a plurality of filter devices that are commonly connected to the common connection terminal, wherein the composite filter device is mounted on a mounting substrate, the plurality of filter devices include a first filter device including an acoustic wave device according to an example embodiment of the present invention, the plurality of filter devices include a second filter device including a second piezoelectric layer, the first filter device and the second filter device are separate components provided on the mounting substrate, and the second piezoelectric layer is a lithium tantalate layer.

According to example embodiments of the present invention, it is possible to provide acoustic wave devices and composite filter devices, which are each able to provide a wide bandwidth and to reduce or prevent unnecessary waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view showing a portion of an acoustic wave device according to a first example embodiment of the present invention.

FIG. 2 is a schematic plan view of the acoustic wave device according to the first example embodiment of the present invention.

FIG. 3 is a schematic view illustrating definitions of silicon crystal axes.

FIG. 4 is a schematic view showing a silicon (111) plane.

FIG. 5 is a graph showing relationships between ψ in Euler angles of a first main surface of a silicon single crystal baseplate and phases of higher order modes at about 7000 MHz.

FIG. 6 is a projection view of a Y-cut X-propagation lithium niobate single crystal layer when seen from.

FIG. 7 is a graph showing relationships between plane orientations of a main surface of the silicon single crystal baseplate, a third Euler angle, and phases of higher order modes at about 7000 MHZ.

FIG. 8 is a schematic elevational cross-sectional view showing a portion of an acoustic wave device according to a modification of the first example embodiment of the present invention.

FIG. 9 is a schematic plan view of an acoustic wave device according to a second example embodiment of the present invention.

FIG. 10 is a schematic plan view of an acoustic wave device according to a third example embodiment of the present invention.

FIG. 11 is a schematic plan view of an acoustic wave device according to a fourth example embodiment of the present invention.

FIG. 12 is a schematic cross-sectional view of an acoustic wave device according to a fifth example embodiment of the present invention along an electrode finger extension direction.

FIG. 13 is a circuit diagram of a filter device according to a sixth example embodiment of the present invention.

FIG. 14 is a schematic view of a composite filter device according to the sixth example embodiment of the present invention.

FIG. 15 is a schematic elevational cross-sectional view showing a structure in which the composite filter device according to the sixth example embodiment of the present invention is mounted on a mounting substrate.

FIG. 16 is a schematic view of a composite filter device according to a seventh example embodiment of the present invention.

### DETAILED DESCRIPTION OF THE EXAMPLE EMBODIMENTS

The present invention is made clear below by describing example embodiments of the present invention with reference to the drawings.

Each example embodiment described in the present description is an exemplification, and structures of different example embodiments can be partially replaced or combined.

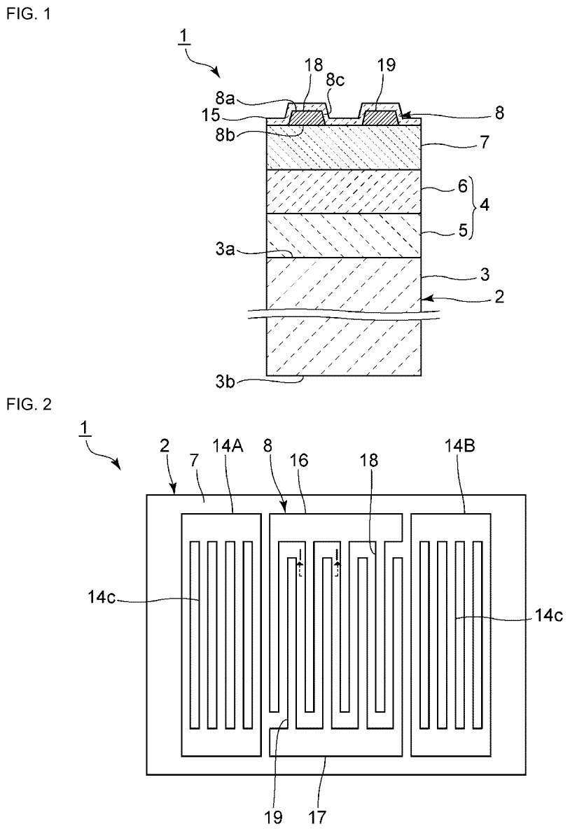

FIG. 1 is a schematic elevational cross-sectional view showing part of an acoustic wave device according to a first example embodiment of the present invention. FIG. 2 is a schematic plan view of the acoustic wave device according to the first example embodiment. It should be noted that FIG. 1 is a schematic cross-sectional view along line I-I in FIG. 2. FIG. 2 does not show a dielectric film described below. This also applies to the schematic views other than FIG. 2.

As shown in FIG. 1, an acoustic wave device 1 includes a piezoelectric substrate 2. The piezoelectric substrate 2 includes a silicon single crystal baseplate 3, an intermediate layer 4, and a lithium niobate layer 7 defining and functioning as a piezoelectric layer. The piezoelectric substrate 2 is a substrate that is piezoelectric.

In the present example embodiment, the intermediate layer 4 is a multilayer body. More specifically, the intermediate layer 4 includes a first layer 5 and a second layer 6. In the piezoelectric substrate 2, the first layer 5 is provided on the silicon single crystal baseplate 3. The second layer 6 is provided on the first layer 5. The lithium niobate layer 7 is provided on the second layer 6.

The silicon single crystal baseplate 3 includes a first main surface 3a and a second main surface 3b. The first main surface 3a and the second main surface 3b face each other. Of the first main surface 3a and the second main surface 3b, the first main surface 3a is a main surface on a side of the lithium niobate layer 7. The first main surface 3a is a main surface of the silicon single crystal baseplate 3.

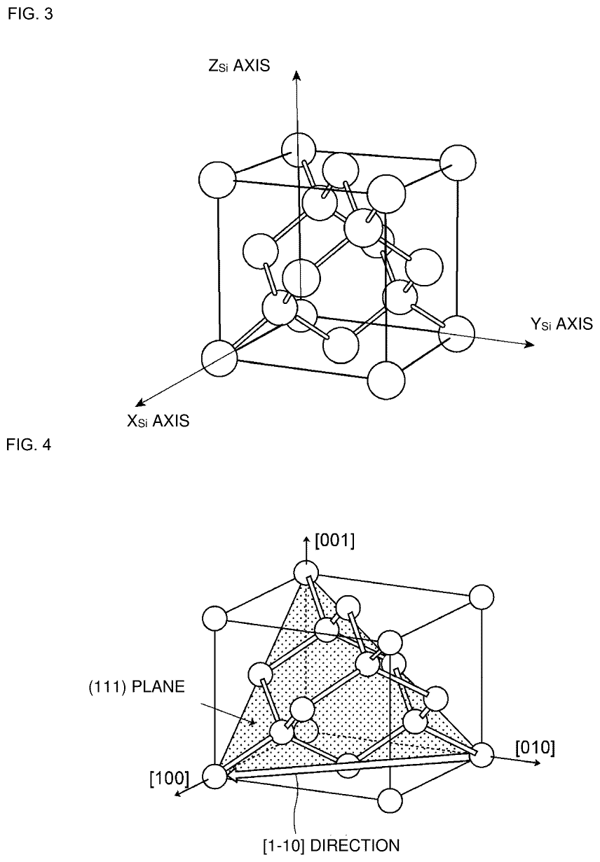

FIG. 3 is a schematic view illustrating definitions of silicon crystal axes. FIG. 4 is a schematic view showing a silicon (111) plane.

As shown in FIG. 3, a silicon single crystal has a diamond structure. In the present description, the crystal axes of silicon of the silicon single crystal baseplate 3 are [X_{Si}, Y_{Si}, Z_{Si}]. In silicon, due to the symmetry of the crystal structure, the X_{Si} axis, the Y_{Si} axis, and the Z_{Si} axis are equivalent.

In the present example embodiment, a plane orientation of the first main surface 3a of the silicon single crystal baseplate 3 is (111). “A plane orientation is (111)” means that, in the crystal structure of silicon having a diamond structure, a cut has been made in the (111) plane orthogonal or substantially orthogonal to a crystal axis represented by a Miller index. That is, the first main surface 3a corresponds to the (111) plane. The (111) plane is a plane shown in FIG. 4. In the (111) plane, there is in-plane three-fold symmetry, and an equivalent crystal structure is provided by a rotation of about 120 degrees. In the present description, the (111) plane also includes a crystallographically equivalent plane.

When Euler angles in the first main surface 3a of the silicon single crystal baseplate 3 are (φ, θ, ψ), φ is about −45 degrees, for example. θ is about −54.73 degrees to two decimal places, for example. In the present example embodiment, ψ is about −30 degrees <ψ< about 30 degrees, for example. In the present description, an angle equivalent to φ is a first Euler angle, an angle equivalent to θ is a second Euler angle, and an angle equivalent to ψ is a third Euler angle.

As materials of the intermediate layer 4, for example, silicon nitride and silicon oxide are used. Specifically, as a material of the first layer 5, for example, silicon nitride is used. As a material of the second layer 6, for example, silicon oxide is used. In the acoustic wave device 1, the composition of silicon nitride is Si₃N₄, for example. The ratio between Si and N in silicon nitride is not limited to 3:4. For example, the composition of silicon nitride may be SiN. On the other hand, for example, the composition of silicon oxide is SiO₂. The ratio between Si and O in silicon oxide is not limited to 1:2.

In example embodiment of the present invention, the intermediate layer 4 may be a single-layer dielectric layer. In this case, as a material of the single-layer intermediate layer 4, for example, silicon nitride or silicon oxide may be used. Nevertheless, the material of the intermediate layer 4 is not limited to the above.

The lithium niobate layer 7 is provided on the intermediate layer 4. That is, in the present example embodiment, the lithium niobate layer 7 is indirectly provided on the first main surface 3a of the silicon single crystal baseplate 3 with the intermediate layer 4 being interposed therebetween. The intermediate layer 4 need not be provided. The lithium niobate layer 7 may be directly provided on the first main surface 3a of the silicon single crystal baseplate 3.

The lithium niobate layer 7 is a single crystal layer. The lithium niobate layer 7 has an X axis, a Y axis, and a Z axis as crystal axes. Further, the lithium niobate layer 7 has a plus surface and a minus surface. The plus surface and the minus surface are surfaces that are determined by a polarization direction of the lithium niobate layer 7. The plus surface is a surface where the polarization direction is on a plus side in the lithium niobate layer 7. The minus surface is a surface where the polarization direction is on a minus side in the lithium niobate layer 7.

The lithium niobate layer 7 is, for example, a Y-cut X-propagation lithium niobate single crystal layer. More specifically, for example, a cut-angle of the lithium niobate layer 7 is about 30 degrees Y. When Euler angles in the lithium niobate layer 7 are (φₚ, θₚ, ψₚ), in the present example embodiment, the Euler angles of the lithium niobate layer 7 are, for example, (0 degrees, 120 degrees, 0 degrees). The cut-angle and the Euler angles of the lithium niobate layer 7 are not limited to the above. The lithium niobate layer 7 need not necessarily be a Y-cut X-propagation lithium niobate single crystal layer.

As shown in FIG. 1, an IDT electrode 8 is provided on the lithium niobate layer 7. By applying an alternating-current voltage to the IDT electrode 8, an acoustic wave is excited. As a result of the lithium niobate layer 7 being a Y-cut X-propagation lithium niobate single crystal layer, it is possible to suitably excite an SH wave as a main mode.

As shown in FIG. 2, a pair of reflectors 14A and 14B are provided on the lithium niobate layer 7, one on each side of the IDT electrode 8 in an acoustic wave propagation direction. Each reflector includes a plurality of reflector electrode fingers 14c. The acoustic wave device 1 of the present example embodiment is, for example, a surface acoustic wave resonator. The acoustic wave device of the present invention can be used in, for example, a filter device or a multiplexer.

In the present example embodiment, the IDT electrode 8 and the reflector 14A and the reflector 14B are provided on the minus surface of the lithium niobate layer 7. Nevertheless, the surface where the IDT electrode 8 and the reflector 14A and the reflector 14B are provided is not limited to the minus surface.

The IDT electrode 8 includes a pair of busbars and a plurality of electrode fingers. The pair of busbars are specifically a first busbar 16 and a second busbar 17. The first busbar 16 and the second busbar 17 face each other. The plurality of electrode fingers are specifically a plurality of first electrode fingers 18 and a plurality of second electrode fingers 19. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The plurality of first electrode fingers 18 and the plurality of second electrode fingers 19 are connected to different electrical potentials.

The first electrode fingers 18 and the second electrode fingers 19 may simply be referred to as electrode fingers below. When a direction of extension of the plurality of electrode fingers is an electrode finger extension direction, in the present example embodiment, the electrode finger extension direction and the acoustic wave propagation direction are orthogonal or substantially orthogonal to each other.

As shown in FIG. 1, each electrode finger of the IDT electrode 8 includes a first surface 8a and a second surface 8b and a side surface 8c. The first surface 8a and the second surface 8b face each other in a thickness direction. Of the first surface 8a and the second surface 8b, the second surface 8b is a surface on a side of the lithium niobate layer 7. The side surface 8c is connected to the first surface 8a and the second surface 8b. When an angle of a corner defined by the second surface 8b and the side surface 8c is an n inclination angle, in the present example embodiment, the inclination angle is about 80 degrees, for example. Nevertheless, the inclination angle is not limited to the above.

The IDT electrode 8 includes a multilayer metal film. More specifically, for example, in the multilayer metal film, a Ti layer, an AlCu layer, and a Ti layer are placed upon each other in this order. The reflector 14A and the reflector 14B are made of the same materials as the IDT electrode 8. Nevertheless, the materials of the IDT electrode 8 and the reflector 14A and the reflector 14B are not limited to the above. Alternatively, the IDT electrode 8 and the reflector 14A and the reflector 14B may each include a single-layer metal film.

In the acoustic wave device 1, when a wavelength that is defined by an electrode finger pitch of the IDT electrode 8 is λ, the thickness of the lithium niobate layer 7 is about 1 λ or less, for example. The electrode finger pitch is a center-to-center distance in the acoustic wave propagation direction between adjacent ones of the first electrode fingers 18 and the second electrode fingers 19. Specifically, when the electrode finger pitch is p, λ=2p.

As shown in FIG. 1, a dielectric film 15 is provided on the lithium niobate layer 7 so as to cover the IDT electrode 8. Therefore, the IDT electrode 8 is unlikely to break. As a material of the dielectric film 15, for example, silicon oxide, silicon nitride, or silicon oxynitride can be used. Nevertheless, the material of the dielectric film 15 is not limited to the above.

When silicon oxide is used as the material of the dielectric film 15, it is possible to decrease an absolute value of a temperature coefficient of frequency (TCF) of the acoustic wave device 1. Therefore, it is possible to improve frequency temperature characteristics of the acoustic wave device 1. On the other hand, when silicon nitride is used as the material of the dielectric film 15, it is possible to increase the moisture resistance of the acoustic wave device 1. Nevertheless, the dielectric film 15 need not be provided.

The present example embodiment includes the following structures. 1) The lithium niobate layer 7 is provided on the first main surface 3a of the silicon single crystal baseplate 3. 2) In the first main surface 3a, the plane orientation is (111) and ψ in the Euler angles (about −45 degrees, about −54.73 degrees, ψ) of the first main surface 3a is about −30 degrees <ψ< about 30 degrees. As in the structure of 1) above, when the lithium niobate layer 7 is used as a piezoelectric layer of the piezoelectric substrate 2, it is possible to make a wider bandwidth between a resonant frequency and an anti-resonant frequency in the acoustic wave device 1 than when a lithium tantalate layer is used as the piezoelectric layer. That is, the bandwidth of the acoustic wave device 1 can be made wide.

As in the structure of 2) above, since ψ in the Euler angles (about −45 degrees, about −54.73 degrees, v) of the first main surface 3a is about −30 degrees <ψ< about 30 degrees, when the lithium niobate layer 7 is used as the piezoelectric layer, it is possible to reduce or prevent unnecessary waves. The advantageous effects of making it possible to reduce or prevent unnecessary waves in the present example embodiment is specifically described below.

In an acoustic wave device having a layer structure as in the first example embodiment, phases of unnecessary waves were measured each time ψ in the Euler angles (about −45 degrees, about −54.73 degrees, v) of a first main surface of a silicon single crystal baseplate was changed. Specifically, phases of higher order modes near 7000 MHz were measured. Design parameters of the acoustic wave device are as follows.

Silicon single crystal baseplate: material . . . Si single crystal, thickness . . . about 50 λ, plane orientation of first main surface . . . (111), Euler angles in first main surface . . . (about −45 degrees, about −54.73 degrees, ψ), ψ in Euler angles . . . changed every 5 degrees in a range of about −60 degrees to about 60 degrees.

First layer of intermediate layer: material . . . Si₃N₄, thickness . . . about 0.15 λ

Second layer of intermediate layer: material . . . about SiO₂, thickness . . . about 0.15 λ

Lithium niobate layer: material . . . 30-degree Y-cut X-propagation LiNbO₃ single crystal, Euler angles . . . (about 0 degrees, about 120 degrees, about 0 degrees), surface where IDT electrode is provided . . . minus surface

IDT electrode: layer structure . . . Ti layer/AlCu layer/Ti layer from a side of lithium niobate layer, thickness . . . about 0.002 λ/0.05 λ/0.006 λ from the side of lithium niobate layer, inclination angle of side surface of electrode finger . . . about 80 degrees
Duty ratio of IDT electrode: about 0.5
Wavelength λ: about 1 μm

Dielectric film: material . . . SiO₂, thickness of portion provided on first surface of electrode fingers of IDT electrode . . . about 0.01 λ, thickness of portion provided on side surface of electrode fingers of IDT electrode . . . about 0.005 λ

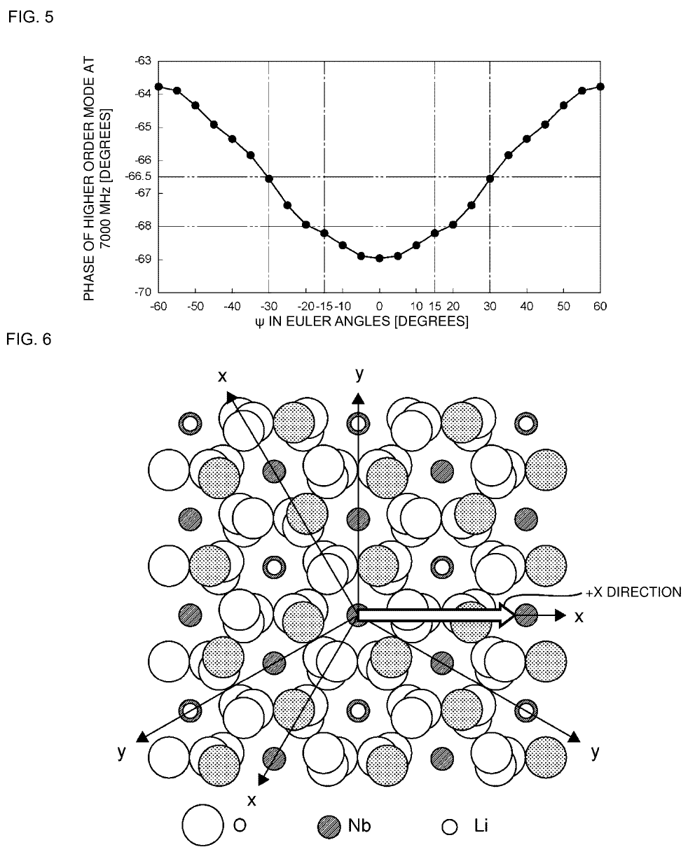

FIG. 5 is a graph showing relationships between ψ in the Euler angles of the first main surface of the silicon single crystal baseplate and phases of higher order modes at about 7000 MHZ.

FIG. 5 shows that, in the range of about −30 degrees <ψ< about 30 degrees, the phases of higher order modes that correspond to unnecessary waves are small. As in the first example embodiment, when ψ is about −30 degrees <ψ< about 30 degrees, it is possible to reduce or prevent unnecessary waves.

Returning to FIG. 1, the first main surface 3a of the silicon single crystal baseplate 3 of the acoustic wave device 1 corresponds to the (111) plane. The lithium niobate layer 7 is a Y-cut X-propagation lithium niobate single crystal layer. In this case, ψ in the Euler angles (about −45 degrees, about −54.73 degrees, v) of the first main surface 3a can be expressed by a direction based on a crystal structure of the silicon single crystal baseplate 3 and a direction based on a crystal structure of the lithium niobate layer 7. The details are described below.

FIG. 6 is a projection view of the Y-cut X-propagation lithium niobate single crystal layer when seen from.

A direction toward an end from a base end of a white arrow in FIG. 6 is a +X direction. The +X direction is one direction of directions of extension of the X axis in the lithium niobate layer 7. On the other hand, a direction toward an end from a base end of a white arrow in FIG. 4 is a [1-10] direction in the silicon single crystal baseplate 3. An angle of a corner defined by the +X direction in the lithium niobate layer 7 and the [1-10] direction in the silicon single crystal baseplate 3 is equivalent to ψ in the Euler angles (about −45 degrees, about-54.73 degrees, v) of the first main surface 3a.

In the first example embodiment, the lithium niobate layer 7 is used as the piezoelectric layer, and the angle of the corner defined by the +X direction in the lithium niobate layer 7 and the [1-10] direction in the silicon single crystal baseplate 3 is greater than about −30 degrees and less than about 30 degrees. Therefore, the bandwidth of the acoustic wave device 1 can be made wide and unnecessary waves can be reduced or prevented.

Further, phases of unnecessary waves were compared in cases where plane orientations of a main surface corresponding to the first main surface of the silicon single crystal baseplate were (111), (100), and (110). In the (111) plane, the (100) plane, and the (110) plane, the phases of unnecessary waves were measured each time a third Euler angle corresponding to ψ in the Euler angles (φ, θ, ψ) was changed every 5 degrees in a range of about −90 degrees to about 90 degrees. Specifically, the phases of higher order modes near 7000 MHz were measured.

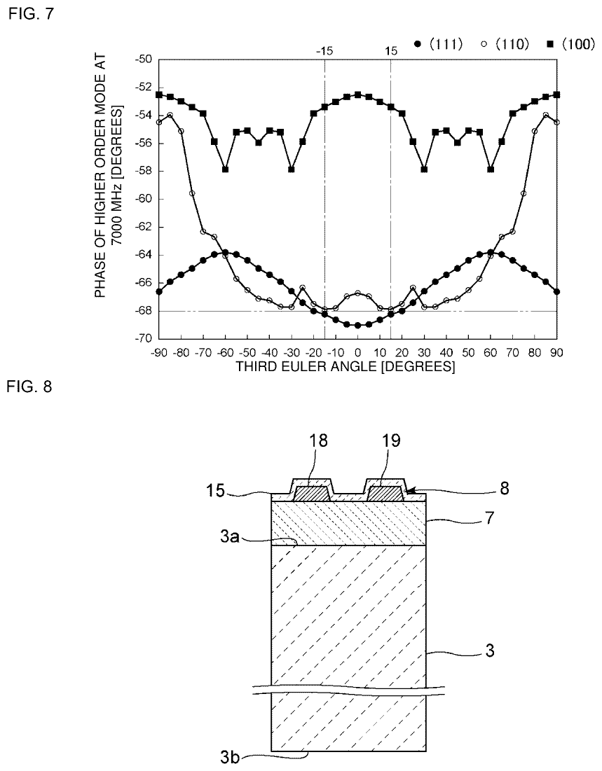

FIG. 7 is a graph showing relationships between the plane orientations of the main surface of the silicon single crystal baseplate, the third Euler angle, and the phases of higher order modes at 7000 MHZ.

As shown in FIG. 7, when the plane orientation of the main surface of the silicon single crystal baseplate is (111) and the third Euler angle is about −15 degrees to about 15 degrees, harmonic waves corresponding to unnecessary waves are reduced or prevented more than when the plane orientation is (110) and when the plane orientation is (100).

Therefore, in the structure of the first example embodiment shown in FIG. 1, it is preferable that the third Euler angle ψ of the first main surface 3a of the silicon single crystal baseplate 3 is about −15 degrees ≤ψ≤ about 15 degrees. Alternatively, it is preferable that the angle of the corner defined by the +X direction in the lithium niobate layer 7 and the [1-10] direction in the silicon single crystal baseplate 3 is about −15 degrees to about 15 degrees. This makes it possible to even further reduce or prevent unnecessary waves.

The first layer 5 of the intermediate layer 4 in the first example embodiment is a high sound velocity film defining and functioning as a high sound velocity material layer. The high sound velocity material layer is a layer where the sound velocity is relatively high. More specifically, the sound velocity of a bulk wave that propagates through the high sound velocity material layer is higher than the sound velocity of an acoustic wave that propagates through the piezoelectric layer. In the first example embodiment, the piezoelectric layer is the lithium niobate layer 7, for example. Examples of the high sound velocity material include piezoelectric materials, such as aluminum nitride, lithium tantalate, lithium niobate, or a crystal, ceramic materials, such as alumina, sapphire, magnesia, silicon nitride, silicon carbide, zirconia, cordierite, mullite, steatite, forsterite, spinel, or sialon, dielectric materials, such as aluminum oxide, silicon oxynitride, DLC (diamond-like carbon), or diamond, semiconductor materials, such as silicon, and a material whose main component is any of the materials above. The spinel includes an aluminum compound including oxygen and one or more elements selected from, for example, Mg, Fe, Zn, or Mn. Examples of the spinel above can include MgAl₂O₄, FeAl₂O₄, ZnAl₂O₄, or MnAl₂O₄.

“Main component” in the present description refers to a component whose proportion is greater than 50 wt %. The material of the main component above may exist in any one of a single crystal state, a polycrystal state, and an amorphous state, or in a state that is a combination of these.

In contrast, the second layer 6 of the intermediate layer 4 is a low sound velocity film. The low sound velocity film is a film where the sound velocity is relatively low. More specifically, the sound velocity of a bulk wave that propagates through the low sound velocity film is lower than the sound velocity of a bulk wave that propagates through the piezoelectric layer. Examples of a material of the low sound velocity film include dielectric materials, such as glass, silicon oxide, silicon oxynitride, lithium oxide, tantalum oxide, or a compound in which fluorine, carbon, or boron is added to silicon oxide, and materials whose main component is any of the materials above.

In the first example embodiment, the first layer 5, defining and functioning as the high sound velocity film, the second layer 6, defining and functioning as the low sound velocity film, and the lithium niobate layer 7, defining and functioning the piezoelectric layer, are placed upon each other in this order. Therefore, it is possible to effectively confine the energy of an acoustic wave on the side of the lithium niobate layer 7.

As shown in FIG. 1, the first main surface 3a of the silicon single crystal baseplate 3 is in contact with the intermediate layer 4. The intermediate layer 4 need not be provided. In a modification of the first example embodiment shown in FIG. 8, the lithium niobate layer 7 is directly provided on the first main surface 3a of the silicon single crystal baseplate 3. The first main surface 3a is in contact with the lithium niobate layer 7. Even in this case, as in the first example embodiment, the bandwidth of the acoustic wave device can be made wide and unnecessary waves can be reduced or prevented.

The acoustic wave device according to the present example embodiment may have a structure that utilizes a piston mode. In this case, it is possible to reduce or prevent a transverse mode. This example is described below.

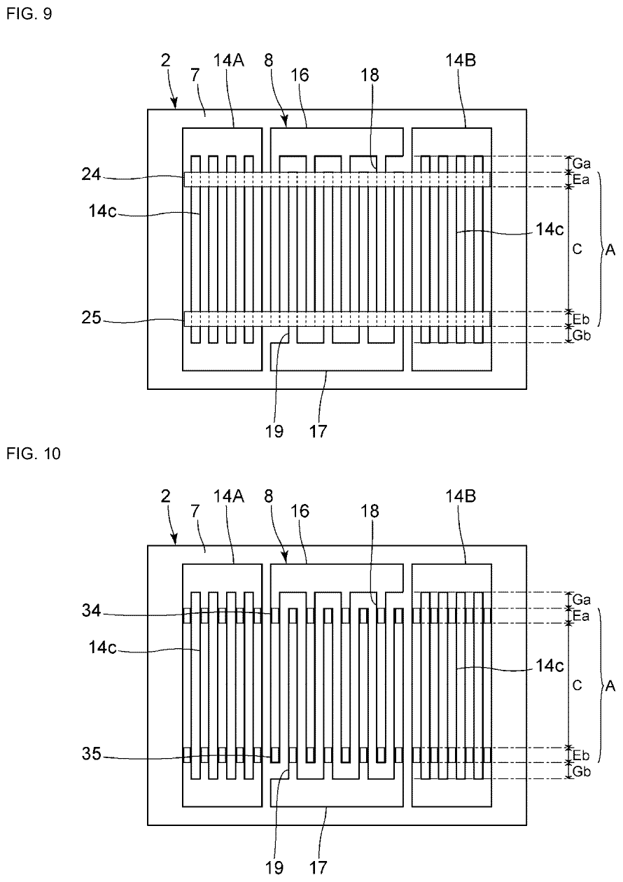

FIG. 9 is a schematic plan view of an acoustic wave device according to a second example embodiment of the present invention.

The present example embodiment differs from the first example embodiment in that a pair of mass adding films are provided. The pair of mass adding films include a first mass adding film 24 and a second mass adding film 25. With regard to points other than the point above, the acoustic wave device of the present example embodiment has the same or substantially the same structure as the acoustic wave device 1 of the first example embodiment. The first mass adding film 24 and the second mass adding film 25 may simply be referred to as mass adding films below.

When an IDT electrode 8 is seen from an acoustic wave propagation direction, a region where adjacent ones of first electrode fingers 18 and second electrode fingers 19 overlap each other is an intersection region A. The intersection region A includes a central region C and a pair of edge regions. The pair of edge regions includes a first edge region Ea and a second edge region Eb. In an electrode finger extension direction, the first edge region Ea and the second edge region Eb face each other with the central region C being interposed therebetween. Of the first edge region Ea and the second edge region Eb, the first edge region Ea is positioned on a side of a first busbar 16. Of the first edge region Ea and the second edge region Eb, the second edge region Eb is positioned on a side of a second busbar 17.

In the present example embodiment, a dimension along the electrode finger extension direction of each edge region is about 0.6 λ, for example. Nevertheless, the dimension along the electrode finger extension direction of each edge region is not limited to the above.

Regions between the intersection region A and the pair of busbars are a pair of gap regions. The pair of gap regions include a first gap region Ga and a second gap region Gb. More specifically, the first gap region Ga is positioned between the first edge region Ea and the first busbar 16. The second gap region Gb is positioned between the second edge region Eb and the second busbar 17.

Even in the first example embodiment, the IDT electrode 8 has the same or substantially the same structure as that in the present example embodiment. Therefore, even in the first example embodiment, it is possible to define the intersection region A and the pair of gap regions.

The first mass adding film 24 and the second mass adding film 25 each have a strip shape. At the first edge region Ea, one first mass adding film 24 is provided over a plurality of electrode fingers. Similarly, at the second edge region Eb, one second mass adding film 25 is provided over the plurality of electrode fingers. The first mass adding film 24 and the second mass adding film 25 are also provided at portions between the electrode fingers on a lithium niobate layer 7.

By providing the first mass adding film 24 at the first edge region Ea, the sound velocity at the first edge region Ea becomes lower than the sound velocity at the central region C. Therefore, a low sound velocity region is formed at the first edge region Ea. The low sound velocity region is a region where the sound velocity is lower than the sound velocity at the central region C. Similarly, even at the second edge region Eb, a low sound velocity region is formed.

In the present example embodiment, the central region C and the pair of low sound velocity regions are disposed in this order from an inner side toward an outer side in the electrode finger extension direction. Therefore, a piston mode is generated. Consequently, it is possible to reduce or prevent the transverse mode.

A mass adding film is to be provided at at least one of the first edge region Ea and the second edge region Eb. Nevertheless, it is preferable that mass adding films are provided at both the first edge region Ea and the second edge region Eb. This makes it possible to more reliably generate the piston mode.

The mass adding films are to overlap in plan view at least one electrode finger of the plurality of electrode fingers. Nevertheless, it is preferable that, in plan view, multiple electrode fingers and the mass adding films overlap each other, and it is more preferable that all of the electrode fingers and the mass adding films overlap each other. This makes it possible to even more reliably generate the piston mode.

In the present description, “plan view” means viewing from a direction corresponding to “above” in FIG. 1. In other words, it means viewing the acoustic wave device from a direction in which the silicon single crystal baseplate 3 and the lithium niobate layer 7 are placed upon each other. In FIG. 1, for example, of a side of the silicon single crystal baseplate 3 and the side of the lithium niobate layer 7, the side of the lithium niobate layer 7 is defined as “above”.

In the present example embodiment, the first mass adding film 24 is placed upon not only the electrode fingers of the IDT electrode 8 but also reflector electrode fingers 14c of each reflector. The second mass adding film 25 is also placed upon the electrode fingers of the IDT electrode 8 and the reflector electrode fingers 14c of each reflector. Nevertheless, the first mass adding film 24 and the second mass adding film 25 need not be placed upon the reflector electrode fingers 14c of each reflector.

As a material of each mass adding film, for example, a dielectric material, tantalum oxide, can be used. Depending upon the material of each mass adding film, the dimensions along the electrode finger extension direction of each mass adding film easily reducing or preventing the transverse mode and the thickness of each mass adding film differ.

In the first gap region Ga, of the first electrode fingers 18 and the second electrode fingers 19, only the first electrode fingers 18 are provided. Therefore, a high sound velocity region is provided in the first gap region Ga. The high sound velocity region is a region where the sound velocity is higher than the sound velocity at the central region C. Similarly, even in the second gap region Gb, a high sound velocity region is provided.

In the present example embodiment, the central region C, the pair of low sound velocity regions, and the pair of high sound velocity regions are disposed in this order from the inner side toward the outer side in the electrode finger extension direction. Therefore, it is possible to even more reliably generate the piston mode.

In addition, even in the present example embodiment, as in the first example embodiment, the lithium niobate layer 7 is indirectly provided on a first main surface 3a of the silicon single crystal baseplate 3 with an intermediate layer 4 being interposed therebetween. At the first main surface 3a, the plane orientation is (111), and ψ in Euler angles of the first main surface 3a is about −30 degrees <ψ< about 30 degrees, for example. Therefore, the bandwidth of the acoustic wave device can be made wide and unnecessary waves can be reduced or prevented.

Although omitted in FIG. 9, even in the present example embodiment, the dielectric film 15 shown in FIG. 1 is provided on the lithium niobate layer 7. At portions where the electrode fingers, the mass adding films, and the dielectric film 15 are placed upon each other, the lithium niobate layer 7, the electrode fingers, the mass adding films, and the dielectric film 15 are placed upon each other in this order. Nevertheless, the order of placement is not limited thereto. For example, the lithium niobate layer 7, the electrode fingers, the dielectric film 15, and the mass adding films may be placed upon each other in this order. In this case, as the material of each mass adding film, a metal may be used.

Alternatively, the lithium niobate layer 7, the mass adding films, the electrode fingers, and the dielectric film 15 may be placed upon each other in this order. In this way, the mass adding films may be provided between the lithium niobate layer 7 and the electrode fingers.

By way of a third example embodiment to a fifth example embodiment of the present invention, other examples utilizing the piston mode are described below. Even in the third example embodiment to the fifth example embodiment, as in the second example embodiment, the bandwidth of an acoustic wave device can be made wide and a transverse mode and harmonic waves corresponding to unnecessary waves can be reduced or prevented.

FIG. 10 is a schematic plan view of an acoustic wave device according to the third example embodiment of the present invention.

The present example embodiment differs from the second example embodiment in that a plurality of first mass adding films 34 are provided at a first edge region Ea and are provided on reflector electrode fingers 14c of each reflector. The present example embodiment also differs from the second example embodiment in that a plurality of second mass adding films 35 are provided at a second edge region Eb and are provided on the reflector electrode fingers 14c of each reflector. With regard to points other than the points above, the acoustic wave device of the present example embodiment has the same or substantially the same structure as the acoustic wave device of the second example embodiment.

Each first mass adding film 34 and each second mass adding film 35 are placed upon one first electrode finger 18, one second electrode finger 19, or one reflector electrode finger 14c. The first mass adding films 34 and the second mass adding films 35 need not be placed upon the reflector electrode fingers 14c of each reflector.

In the present example embodiment, each first mass adding film 34 and each second mass adding film 35 do not contact multiple electrode fingers that are connected to different electrical potentials. In this case, as a material of each first mass adding film 34 and a material of each second mass adding film 35, for example, a metal may be used. Nevertheless, as the material of each first mass adding film 34 and the material of each second mass adding film 35, a dielectric material may be used, for example.

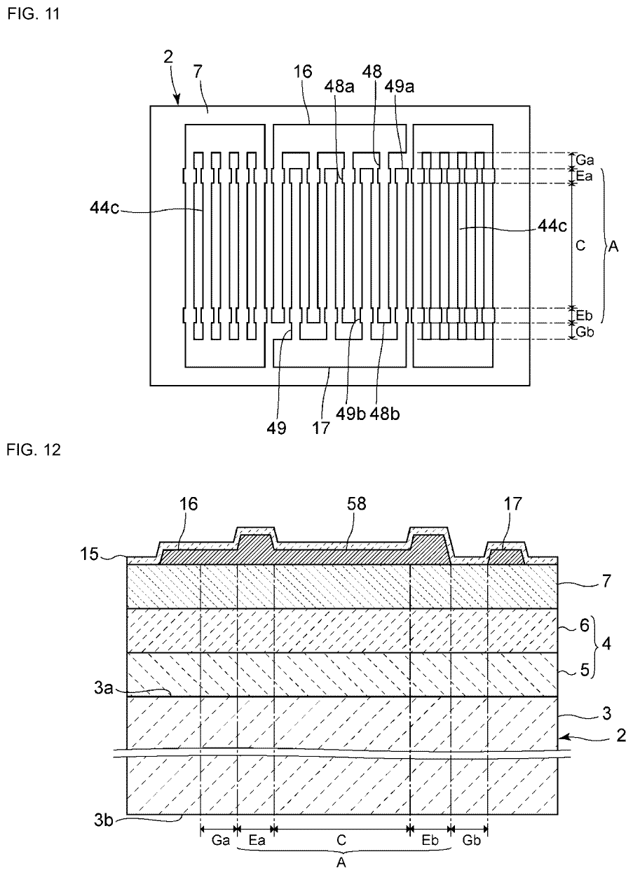

FIG. 11 is a schematic plan view of an acoustic wave device according to the fourth example embodiment of the present invention.

The present example embodiment differs from the first example embodiment in the shape of each electrode finger. Specifically, in the first example embodiment, the width of each electrode finger is constant. In contrast, in the present example embodiment, the width of each electrode finger is not constant. The width of each electrode finger is a dimension along an acoustic wave propagation direction of each electrode finger. The present example embodiment also differs from the first example embodiment in the shape of each reflector electrode finger 44c. With regard to points other than the points above, the acoustic wave device of the present example embodiment has the same or substantially the same structure as the acoustic wave device 1 of the first example embodiment.

More specifically, the plurality of first electrode fingers 48 and the plurality of second electrode fingers 49 each include wide width portions. More specifically, each first electrode finger 48 includes a wide width portion 48a and a wide width portion 48b. The wide width portion 48a is positioned at a first edge region Ea. The wide width portion 48b is positioned at a second edge region Eb. The widths of each electrode finger at the wide width portions are wider than the width of each electrode finger at a central region C.

Similarly, each second electrode finger 49 includes a wide width portion 49a and a wide width portion 49b. The wide width portion 49a is positioned at the first edge region Ea. The wide width portion 49b is positioned at the second edge region Eb.

Since each electrode finger includes the wide width portions, the sound velocities at both edge regions are lower than the sound velocity at the central region C. Therefore, even at both of the edge regions, low sound velocity regions are provided.

A wide width portion of each electrode finger is to be positioned at at least one of the first edge region Ea and the second edge region Eb. Nevertheless, it is preferable that wide width portions are positioned at both the first edge region Ea and the second edge region Eb. This makes it possible to more reliably generate the piston mode.

At least one electrode finger is to include wide width portions. Nevertheless, it is preferable that multiple electrode fingers include wide width portions, and it is more preferable that all of the electrode fingers include wide width portions. This makes it possible to more reliably generate the piston mode.

The electrode fingers may include the wide width portions, and the mass adding films above may be provided. Even in this case, it is possible to generate the piston mode.

In example embodiments of the present invention, the width of each electrode finger at each edge region may be narrower than the width of each electrode finger at the central region C.

In the present example embodiment, similarly to the plurality of first electrode fingers 48 and the plurality of second electrode fingers 49, the plurality of reflector electrode fingers 44c of each reflector each include wide width portions. Nevertheless, each reflector electrode finger 44c need not include wide width portions.

FIG. 12 is a schematic cross-sectional view of an acoustic wave device according to a fifth example embodiment of the present invention along an electrode finger extension direction.

The present example embodiment differs from the first example embodiment in the shape of each electrode finger. Specifically, in the first example embodiment, the thickness of each electrode finger is constant. In contrast, in the present example embodiment, the thickness of each electrode finger is not constant. With regard to points other than the points above, the acoustic wave device of the present example embodiment has the same or substantially the same structure as the acoustic wave device 1 of the first example embodiment.

More specifically, the thickness of a portion of a first electrode finger 58 that is positioned at a first edge region Ea is larger than the thickness of a portion of the first electrode finger 58 that is positioned at a central region C. The thickness of a portion of the first electrode finger 58 that is positioned at a second edge region Eb is larger than the thickness of the portion of the first electrode finger 58 that is positioned at the central region C.

Similarly, the thickness of a portion of a second electrode finger that is positioned at the first edge region Ea is larger than the thickness of a portion of the second electrode finger that is positioned at the central region C. The thickness of a portion of the second electrode finger that is positioned at the second edge region Eb is larger than the thickness of the portion of the second electrode finger that is positioned at the central region C.

Since the thickness of each electrode finger differs, the sound velocities at both edge regions are lower than the sound velocity at the central region C. Therefore, even at both the edge regions, low sound velocity regions are provided.

The thickness of each electrode finger is to be larger at at least one of the first edge region Ea and the second edge region Eb than at the central region C. Nevertheless, it is preferable that the thickness of each electrode finger is larger at both the first edge region Ea and the second edge region Eb than at the central region C. This makes it possible to more reliably generate the piston mode.

The thicknesses of portions of at least one electrode finger that are positioned at a corresponding one of the edge regions are to be larger than the thickness of a portion thereof that is positioned at the central region C. Nevertheless, it is preferable that the thicknesses of portions of multiple electrode fingers that are positioned at a corresponding one of the edge regions are larger than the thickness of a portion thereof that is positioned at the central region C, and it is more preferable that the thicknesses of portions of all of the electrode fingers that are positioned at a corresponding one of the edge regions be larger than the thickness of a portion thereof that is positioned at the central region C. This makes it possible to more reliably generate the piston mode.

In example embodiments of the present invention, the thickness of each electrode finger at each edge region may be smaller than the thickness of each electrode finger at the central region C.

The acoustic wave devices according to example embodiments of the present invention can be used in a filter device or a composite filter device, such as a multiplexer. Examples thereof are described below.

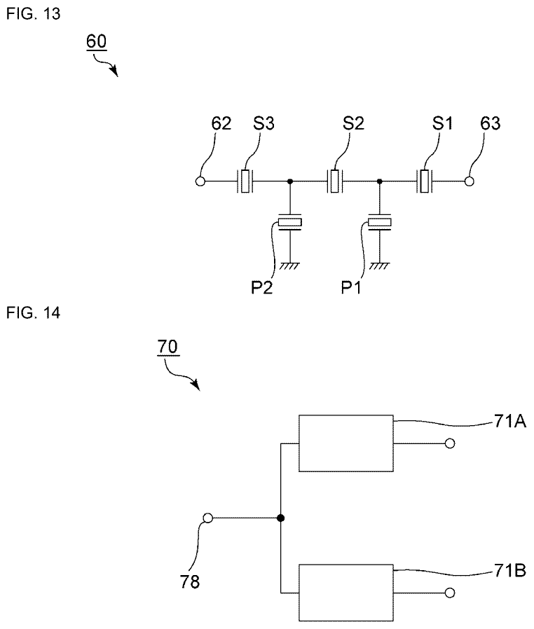

FIG. 13 is a circuit diagram of a filter device according to a sixth example embodiment of the present invention.

A filter device 60 is a ladder filter, for example. In the present example embodiment, the filter device 60 is a transmission filter, for example. Nevertheless, the filter device 60 may be a reception filter, for example. The filter device 60 is mounted on, for example, a mounting substrate.

The filter device 60 includes a first signal terminal 62 and a second signal terminal 63, and a plurality of series arm resonators and a plurality of parallel arm resonators. In the present example embodiment, all of the series arm resonators and all of the parallel arm resonators are acoustic wave resonators, for example. All of the series arm resonators and all of the parallel arm resonators share a piezoelectric substrate. All of the series arm resonators and all of the parallel arm resonators of the filter device 60 are acoustic wave devices according to example embodiments of the present invention.

The first signal terminal 62 and the second signal terminal 63 may each be, for example, an electrode pad or a wire. In the present example embodiment, the first signal terminal 62 is an antenna terminal. The antenna terminal is connected to an antenna.

The plurality of series arm resonators of the filter device 60 include a series arm resonator S1, a series arm resonator S2, and a series arm resonator S3. The plurality of parallel arm resonators include a parallel arm resonator P1 and a parallel arm resonator P2.

The series arm resonator S1, the series arm resonator S2, and the series arm resonator S3 are connected in series between the first signal terminal 62 and the second signal terminal 63. The parallel arm resonator P1 is connected between a ground electrical potential and a connection point between the series arm resonator S1 and the series arm resonator S2. The parallel arm resonator P2 is connected between a ground electrical potential and a connection point between the series arm resonator S2 and the series arm resonator S3. A circuit structure of the filter device 60 is not limited to the above. When the filter device 60 is a ladder filter, for example, the filter device 60 is to include at least one series arm resonator and at least one parallel arm resonator. Alternatively, the filter device 60 may include a longitudinally coupled resonator acoustic wave filter, for example.

Although not shown, the first signal terminal 62 and the second signal terminal 63 and a plurality of ground terminals are provided on a lithium niobate layer of a piezoelectric substrate. The plurality of ground terminals to ground electrical potentials. In a structure in which the filter device 60 is mounted on a mounting substrate, the first signal terminal 62, the second signal terminal 63, and the plurality of ground terminals are joined to the mounting substrate. For the joining of each terminal and the mounting substrate, for example, a bump or a suitable conductive adhesive can be used.

The filter devices according to example embodiments of the present invention may have a WLP (Wafer Level Package) structure, for example. In this case, a support is provided on the lithium niobate layer of the piezoelectric substrate so as to surround an IDT electrode in each of a plurality of acoustic wave resonators. A cover is provided on the support. Therefore, a hollow portion surrounded by the piezoelectric substrate, the support, and the cover is provided. Each IDT electrode is positioned in the hollow portion. A plurality of through electrodes that extend through the support and the cover are provided. One end of each through electrode is connected to each terminal. The other end of each through electrode is joined to, for example, a bump.

The filter device 60 includes the acoustic wave resonators, which are acoustic wave devices according to example embodiments of the present invention. Therefore, as in, for example, the first example embodiment, the bandwidth of each acoustic wave resonator of the filter device 60 can be made wide. Consequently, a pass band of the filter device 60 can be easily made wide. In addition, in the acoustic wave resonators of the filter device 60, it is possible to reduce or prevent unnecessary waves. Therefore, when the filter device 60 is used in a composite filter device, it is possible to reduce or prevent the effects of unnecessary waves on other filter devices.

FIG. 14 is a schematic view of a composite filter device according to a sixth example embodiment of the present invention.

A composite filter device 70 is a multiplexer, for example. More specifically, the composite filter device 70 is a duplexer, for example. The composite filter device 70 includes a first filter device 71A and a second filter device 71B, and a common connection terminal 78. The first filter device 71A and the second filter device 71B are commonly connected to the common connection terminal 78. The common connection terminal 78 may be, for example, an electrode pad or a wire. In the present example embodiment, the common connection terminal 78 is an antenna terminal.

The first filter device 71A is a filter device according to an example embodiment of the present invention. In contrast, the second filter device 71B is not a filter device according to an example embodiment of the present invention. Specifically, the first filter device 71A and the second filter device 71B include separate piezoelectric substrates. The structure of the piezoelectric substrate of the second filter device 71B differs from the structure of the piezoelectric substrate of the acoustic wave device according to an example embodiment of the present invention.

The composite filter device 70 is mounted on, for example, a mounting substrate. The first filter device 71A and the second filter device 71B are separate components provided on the mounting substrate.

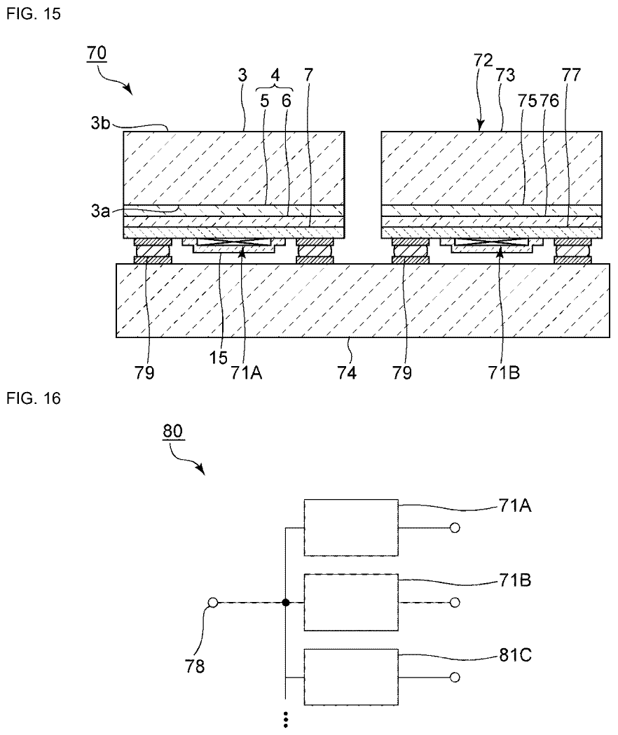

FIG. 15 is a schematic elevational cross-sectional view showing a structure in which the composite filter device according to the sixth example embodiment is mounted on the mounting substrate. FIG. 15 schematically shows IDT electrodes and reflectors with two diagonals added to rectangles.

The first filter device 71A and the second filter device 71B are each mounted on a mounting substrate 74 by flip chip mounting. Specifically, each terminal of the first filter device 71A is joined to the mounting substrate 74 by a bump 79. Similarly, each terminal of the second filter device 71B is joined to the mounting substrate 74 by a bump 79. The first filter device 71A and the second filter device 71B may each have a WLP structure, for example.

In the description below, the piezoelectric substrate of the acoustic wave device according to the present example embodiment is a first piezoelectric substrate, and the piezoelectric layer thereof is a first piezoelectric layer. Nevertheless, the first piezoelectric substrate of the present example embodiment has the same or substantially the same structure as the piezoelectric substrate 2 of the acoustic wave device 1 according to the first example embodiment shown in FIG. 1. The first piezoelectric layer is, for example, a lithium niobate layer 7 shown in FIG. 15.

In contrast, the second filter device 71B includes a second piezoelectric substrate 72. The second piezoelectric substrate 72 includes a support baseplate 73, a third layer 75, a fourth layer 76, and a second piezoelectric layer. The second piezoelectric layer is, for example, a lithium tantalate layer 77. The support baseplate 73, the third layer 75, the fourth layer 76, and the lithium tantalate layer 77 are placed upon each other in this order. In the composite filter device 70, a material of the first piezoelectric layer of the first filter device 71A and a material of the second piezoelectric layer of the second filter device 71B differ from each other.

An IDT electrode of each acoustic wave resonator of the second filter device 71B is provided on the lithium tantalate layer 77.

As a material of the support baseplate 73, for example, a semiconductor material, such as silicon, or a ceramic material, such as aluminum oxide, can be used.

The third layer 75 is a high sound velocity member. More specifically, in the present example embodiment, the third layer 75 is a high sound velocity film. The sound velocity of a bulk wave that propagates through the third layer 75 is higher than the sound velocity of an acoustic wave that propagates through the second piezoelectric layer. In the present example embodiment, the second piezoelectric layer is, for example, the lithium tantalate layer 77.

The third layer 75 may be a high sound velocity support baseplate defining and functioning as a high sound velocity member. In this case, the second piezoelectric substrate 72 need not include the support baseplate 73.

The fourth layer 76 is a low sound velocity film. The sound velocity of a bulk wave that propagates through the fourth layer 76 is lower than the sound velocity of a bulk wave that propagates through the second piezoelectric layer.

The lithium tantalate layer 77 defining and functioning as the second piezoelectric layer is indirectly provided on the third layer 75 with the fourth layer 76 being interposed therebetween. Nevertheless, the lithium tantalate layer 77 may be directly provided on the third layer 75. Alternatively, the second piezoelectric substrate 72 may be a multilayer body of the support baseplate 73 and the lithium tantalate layer 77. The second piezoelectric substrate 72 may be a lithium tantalate substrate, for example.

The composite filter device 70 includes the first filter device 71A including an acoustic wave device according to an example embodiment of the present invention. Therefore, a pass band of the first filter device 71A of the composite filter device 70 can be easily made wide. In addition, in an acoustic wave resonator of the first filter device 71A, it is possible to reduce or prevent unnecessary waves. Therefore, it is possible to reduce or prevent the effects of unnecessary waves on the second filter device 71B.

FIG. 16 is a schematic view of a composite filter device according to a seventh example embodiment of the present invention.

A composite filter device 80 is a multiplexer, for example. The composite filter device 80 includes a plurality of filter devices and a common connection terminal 78. The plurality of filter devices are commonly connected to the common connection terminal 78.

The plurality of filter devices include a first filter device 71A, a second filter device 71B, a third filter device 81C, and at least one other filter device. The first filter device 71A and the second filter device 71B each have the same or substantially the same structure as the structure of the sixth example embodiment. The third filter device 81C and the other filter device have different pass bands.

The third filter device 81C may be a duplexer, for example. In this case, a communication band of a duplexer including the first filter device 71A and the second filter device 71B and a communication band of the third filter device 81C differ from each other. Nevertheless, the first filter device 71A and the second filter device 71B need not necessarily define a duplexer. Alternatively, the composite filter device 80 may include a plurality of first filter devices 71A. In this case, each first filter device 71A is to be a filter device including an acoustic wave device according to an example embodiment of the present invention. The plurality of first filter devices 71A may have different circuit structures, different acoustic wave resonator structures, or different design parameters. The composite filter device 80 may include a plurality of second filter devices 71B. In this case, each second filter device 71B is to include the second piezoelectric substrate described in the sixth example embodiment. The plurality of second filter devices 71B may have different circuit structures, different acoustic wave resonator structures, or different design parameters.

Even in the present example embodiment, as in the sixth example embodiment, a pass band of the first filter device 71A of the composite filter device 80 can be easily made wide. In addition, in an acoustic wave resonator of the first filter device 71A, it is possible to reduce or prevent unnecessary waves. Therefore, it is possible to reduce or prevent the effects of unnecessary waves on the other filter devices.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a silicon single crystal baseplate including a main surface;
a piezoelectric layer directly or indirectly on the main surface of the silicon single crystal baseplate; and
an interdigital transducer (IDT) electrode directly or indirectly on the piezoelectric layer and including a plurality of electrode fingers; wherein
the piezoelectric layer includes a lithium niobate layer;
in the main surface of the silicon single crystal baseplate, a plane orientation is (111); and
when Euler angles in the main surface of the silicon single crystal baseplate are (φ, θ, ψ), the ψ in the Euler angles of the silicon single crystal baseplate is about −30 degrees <ψ< about 30 degrees.

2. The acoustic wave device according to claim 1, wherein the ψ in the Euler angles of the silicon single crystal baseplate is about −15 degrees ≤ψ≤ about 15 degrees.

3. The acoustic wave device according to claim 1, further comprising:
an intermediate layer between the silicon single crystal baseplate and the piezoelectric layer; wherein
the piezoelectric layer is indirectly on the main surface of the silicon single crystal baseplate with the intermediate layer being interposed therebetween, and the main surface of the silicon single crystal baseplate is in contact with the intermediate layer.

4. The acoustic wave device according to claim 3, wherein
the intermediate layer includes a single-layer dielectric layer; and
the intermediate layer includes silicon oxide.

5. The acoustic wave device according to claim 3, wherein
the intermediate layer includes a first layer and a second layer;
the first layer is on the silicon single crystal baseplate, the second layer is on the first layer, and the piezoelectric layer is on the second layer;
a sound velocity of a bulk wave propagating through the first layer is higher than a sound velocity of an acoustic wave propagating through the piezoelectric layer; and
a sound velocity of a bulk wave propagating through the second layer is lower than a sound velocity of a bulk wave propagating through the piezoelectric layer.

6. The acoustic wave device according to claim 1, wherein
the piezoelectric layer is directly on the main surface of the silicon single crystal baseplate; and
the main surface of the silicon single crystal baseplate is in contact with the piezoelectric layer.

7. The acoustic wave device according to claim 1, wherein, when a wavelength that is defined by an electrode finger pitch of the IDT electrode is λ, a thickness of the piezoelectric layer is about 1 λ or less.

8. The acoustic wave device according to claim 1, wherein
the piezoelectric layer includes an X axis, a Y axis, and a Z axis as crystal axes; and
the piezoelectric layer is a Y-cut X-propagation lithium niobate single crystal layer.

9. The acoustic wave device according to claim 1, further comprising a dielectric film on the piezoelectric layer and covering the IDT electrode.

10. The acoustic wave device according to claim 9, wherein, the dielectric film includes silicon oxide or silicon nitride.

11. The acoustic wave device according to claim 1, wherein
when a direction of extension of the plurality of electrode fingers is an electrode finger extension direction and, when the IDT electrode is seen from an acoustic wave propagation direction orthogonal or substantially orthogonal to the electrode finger extension direction, a region where adjacent ones of the plurality of electrode fingers overlap each other is an intersection region;
the intersection region includes a central region and a pair of edge regions facing each other with the central region being interposed therebetween in the electrode finger extension direction; and
the acoustic wave device further includes a mass adding film at at least one of the pair of edge regions so as to overlap at least one of the electrode fingers in plan view.

12. The acoustic wave device according to claim 1, wherein
when a direction of extension of the plurality of electrode fingers is an electrode finger extension direction and, when the IDT electrode is seen from an acoustic wave propagation direction orthogonal or substantially orthogonal to the electrode finger extension direction, a region where adjacent ones of the electrode fingers overlap each other is an intersection region;
the intersection region includes a central region and a pair of edge regions facing each other with the central region being interposed therebetween in the electrode finger extension direction; and
at least one of the plurality of electrode fingers includes a wide width portion at at least one of the pair of edge regions.

13. An acoustic wave device comprising:
a silicon single crystal baseplate including a main surface;
a piezoelectric layer directly or indirectly on the main surface of the silicon single crystal baseplate; and
an interdigital transducer (IDT) electrode on the piezoelectric layer and that includes a plurality of electrode fingers; wherein
in the main surface of the silicon single crystal baseplate, a plane orientation is (111);
the piezoelectric layer includes an X axis, a Y axis, and a Z axis as crystal axes, and the piezoelectric layer is a Y-cut X-propagation lithium niobate layer; and
when one direction of directions of extension of the X axis of the piezoelectric layer is a +X direction, an angle of a corner defined by the +X direction and a [1-10] direction in the silicon single crystal baseplate is about −15 degrees to about 15 degrees.

14. A composite filter device comprising:
a common connection terminal; and
a plurality of filter devices commonly connected to the common connection terminal; wherein
the composite filter device is mounted on a mounting substrate;
the plurality of filter devices include a first filter device including the acoustic wave device according to claim 1;
the plurality of filter devices include a second filter device including a second piezoelectric layer;
the first filter device and the second filter device are separate components on the mounting substrate; and
the second piezoelectric layer includes a lithium tantalate layer.

15. The composite filter device according to claim 14, wherein
the second filter device includes a third layer;
the second piezoelectric layer is directly or indirectly on the third layer; and
a sound velocity of a bulk wave that propagates through the third layer is higher than a sound velocity of an acoustic wave that propagates through the second piezoelectric layer.

16. The composite filter device according to claim 14, wherein the ψ in the Euler angles of the silicon single crystal baseplate is about −15 degrees ≤ψ≤ about 15 degrees.

17. The composite filter device according to claim 14, further comprising:
an intermediate layer between the silicon single crystal baseplate and the piezoelectric layer; wherein
the piezoelectric layer is indirectly on the main surface of the silicon single crystal baseplate with the intermediate layer being interposed therebetween, and the main surface of the silicon single crystal baseplate is in contact with the intermediate layer.

18. The composite filter device according to claim 17, wherein
the intermediate layer includes a single-layer dielectric layer; and
the intermediate layer includes silicon oxide.

19. The composite filter device according to claim 17, wherein
the intermediate layer includes a first layer and a second layer;
the first layer is on the silicon single crystal baseplate, the second layer is on the first layer, and the piezoelectric layer is on the second layer;
a sound velocity of a bulk wave propagating through the first layer is higher than a sound velocity of an acoustic wave propagating through the piezoelectric layer; and
a sound velocity of a bulk wave propagating through the second layer is lower than a sound velocity of a bulk wave propagating through the piezoelectric layer.

20. The composite filter device according to claim 14, wherein
the piezoelectric layer is directly on the main surface of the silicon single crystal baseplate; and
the main surface of the silicon single crystal baseplate is in contact with the piezoelectric layer.
